(19) United States
(12) Patent Application Publication
(10) Pub. No.: US 2025/0237678 A1
(43) Pub. Date: Jul. 24, 2025

(54) CURRENT SENSOR

(71) Applicant: Asahi Kasei Microdevices Corporation, Tokyo (JP)

(72) Inventors: Masato INOUE, Tokyo (JP); Ryuji NOBIRA, Tokyo (JP); Masaki TSUJIMOTO, Tokyo (JP); Toshiaki KAWASAKI, Tokyo (JP)

(21) Appl. No.: 19/032,502

(22) Filed: Jan. 21, 2025

(30) Foreign Application Priority Data
Jan. 22, 2024 (JP) 2024-007181
Jan. 16, 2025 (JP) 2025-006351

(51) Int. Cl. G01R 15/20; G01R 33/00

(52) U.S. Cl. CPC G01R 15/205; G01R 15/207; G01R 33/0047

(57) ABSTRACT

There is provided a current sensor including: a conductor having a first terminal portion for inputting a current and a second terminal portion for outputting the current which are arranged on one side in a first axial direction, the second terminal portion being separated from the first terminal portion in a second axial direction intersecting the first axial direction, a turn portion which is arranged on another side in the first axial direction, a first body portion which connects one end of the turn portion and the first terminal portion, and a second body portion which is separated from the first body portion in the second axial direction, to connect another end of the turn portion and the second terminal portion; a magnetic sensor which is arranged on the conductor or near the conductor; and a package.

The contents of the following patent application(s) are incorporated herein by reference:
NO. 2024-007181 filed in JP on Jan. 22, 2024
NO. 2025-006351 filed in JP on Jan. 16, 2025

### BACKGROUND

### 1. Technical Field

The present invention relates to a current sensor.

### 2. Related Art

A current sensor in which a conductor through which the current to be measured flows and a magnetoelectric conversion element close to the conductor are encapsulated in a package; and the magnetoelectric conversion element is used to detect a strength of a magnetic field that is generated by the current to be measured flowing through the conductor and convert it into an electrical signal, thereby detecting an amount of current, is known. In such a current sensor, in order to enhance the detection sensitivity by concentrating the magnetic field on the magnetoelectric conversion element, a cross sectional area of a conductor portion that is close to the magnetoelectric conversion element inside the package, is set to be smaller than a cross sectional area of a conductor portion that is positioned on a periphery of the package, thereby increasing a current density in the conductor. In this manner, in a case where an overcurrent flows due to a failure or the like, there is a concern that the conductor inside the package overheats to cause the failure of the sensor. Patent Document 1 discloses a pyrotechnic disconnect that prevents a damage to a sensor by discharging an electric arc, which occurs due to the overcurrent during the failure, to a splitter side. However, typically, it is difficult to detect the failure occurring inside the package.

### PRIOR ART DOCUMENTS

### Patent Document

Patent Document 1: International Publication No. WO 2017/136221

### SUMMARY

In one aspect of the present invention, provided is a current sensor including: a conductor having a first terminal portion for inputting a current and a second terminal portion for outputting the current which are arranged on one side in a first axial direction, the second terminal portion being separated from the first terminal portion in a second axial direction intersecting the first axial direction, a turn portion which is arranged on another side in the first axial direction, a first body portion which connects one end of the turn portion and the first terminal portion, and a second body portion which is separated from the first body portion in the second axial direction, to connect another end of the turn portion and the second terminal portion; a magnetic sensor which is arranged on the conductor or near the conductor; and a package which encapsulates the turn portion, the first body portion, and the second body portion of the conductor, and the magnetic sensor, and which exposes the first terminal portion and the second terminal portion, in which at least one of a cross sectional area of a connection portion between the first terminal portion and the first body portion, or a cross sectional area of a connection portion between the second terminal portion and the second body portion, is smaller than a cross sectional area of the turn portion.

In one aspect of the present invention, provided is a current sensor including: a conductor having a first terminal portion for inputting a current and a second terminal portion for outputting the current which are arranged on one side in a first axial direction, the second terminal portion being separated from the first terminal portion in a second axial direction intersecting the first axial direction, a turn portion which is arranged on another side in the first axial direction, a first body portion which connects one end of the turn portion and the first terminal portion, and a second body portion which is separated from the first body portion in the second axial direction, to connect another end of the turn portion and the second terminal portion; a magnetic sensor which is arranged on the conductor or near the conductor; and a package which encapsulates the turn portion, the first body portion, and the second body portion of the conductor, and the magnetic sensor, and which exposes the first terminal portion and the second terminal portion, in which at least one of a cross sectional area of a cross section of the first terminal portion, which is taken along an outer plane of the package, or a cross sectional area of a cross section of the second terminal portion, which is taken along the outer plane of the package, is smaller than a cross sectional area of the turn portion, a connection portion between the first body portion and the turn portion, and a connection portion between the second body portion and the turn portion, have an approximately rectangular shape in a top plan view, and the magnetic sensor is arranged on at least one of the connection portion between the first body portion and the turn portion, or the connection portion between the second body portion and the turn portion.

There is provided a current sensor including: a conductor having a first terminal portion for inputting a current and a second terminal portion for outputting the current which are arranged on one side in a first axial direction, the second terminal portion being separated from the first terminal portion in a second axial direction intersecting the first axial direction, a turn portion which is arranged on another side in the first axial direction, a first body portion which connects one end of the turn portion and the first terminal portion, and a second body portion which is separated from the first body portion in the second axial direction, to connect another end of the turn portion and the second terminal portion; a magnetic sensor which is arranged on the conductor or near the conductor; and a package which encapsulates the turn portion, the first body portion, and the second body portion of the conductor, and the magnetic sensor, and which exposes the first terminal portion and the second terminal portion, in which at least one of a cross sectional area of a cross section of the first terminal portion, which is taken along an outer plane of the package, or a cross sectional area of a cross section of the second terminal portion, which is taken along the outer plane of the package, is smaller than a cross sectional area of the turn portion, the connection portion between the first body portion and the turn portion, and the connection portion between the second body portion and the turn portion, have a rectangular shape in a top plan view, and the magnetic sensor is arranged on at least one of the connection portion between the first body portion and the turn portion, or the connection portion between the second body portion and the turn portion.

Note that the summary clause does not necessarily describe all necessary features of the embodiments of the present invention. The present invention may also be a sub-combination of the features described above.

### BRIEF DESCRIPTION OF THE DRAWINGS

FIG. 1 shows an internal configuration of a current sensor according to the present embodiment, in a top plan view.

FIG. 2A shows a schematic configuration of a sensor unit.

FIG. 2B shows a definition of rectangularity.

FIG. 2C shows a configuration of the current sensor including two magnetic sensors, in a top plan view.

FIG. 2D shows a schematic configuration of the sensor unit in the two magnetic sensors.

FIG. 3 shows definitions of a cross section and a width of a conductor.

FIG. 4A shows a definition of a cross section of the conductor.

FIG. 4B shows a relationship between an aspect ratio of a cross section of the conductor of a rectangular shape, and a resistance fluctuation rate due to a skin effect.

FIG. 4C shows a relationship between a resistance and a frequency in the conductor.

FIG. 4D shows the current sensor having a small aspect ratio of a cross section of a turn portion, in a top plan view.

FIG. 4E shows the current sensor having a great aspect ratio of a cross section of the turn portion, in a top plan view.

FIG. 5A shows a configuration of a mounting substrate on which the current sensor is disposed, in a top plan view.

FIG. 5B shows a configuration of the current sensor and a footprint, in a top plan view.

FIG. 6A shows an arrangement of the conductor, a dielectric layer, and the magnetic sensor, in a top plan view.

FIG. 6B shows an arrangement of the conductor, the dielectric layer, and the magnetic sensor at a cross section A-A′ of FIG. 6A, in a side view.

FIG. 6C shows an arrangement of the conductor, the dielectric layer, and the magnetic sensor at the cross section A-A′ of FIG. 6A, in a side view.

FIG. 7A shows a configuration of the current sensor according to a first modified example, in a top plan view.

FIG. 7B shows a configuration of the current sensor according to a second modified example, in a top plan view.

FIG. 7C shows a configuration of the current sensor according to a third modified example, in a top plan view.

FIG. 7D shows a configuration of the current sensor according to a fourth modified example, in a top plan view.

FIG. 7E shows a configuration of the current sensor according to a fifth modified example, in a top plan view.

FIG. 7F shows a configuration of the current sensor according to a sixth modified example, in a top plan view.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solution of the invention.

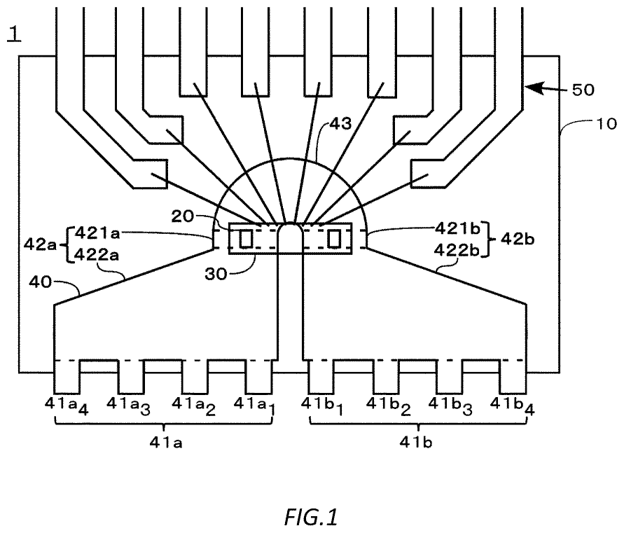

FIG. 1 shows an internal configuration of a current sensor 1 according to the present embodiment, in a top plan view in which a package 10 is seen through. Here, an up and down direction in the figure is defined as a vertical direction, and a right and left direction is defined as a horizontal direction. The current sensor 1 is a sensor which: measures a current amount of a current to be measured by using a magnetic sensor 30 to detect a magnetic field that is generated around a conductor 40 by the current to be measured flowing through the conductor 40; and includes the package 10, the magnetic sensor 30, the conductor 40, and a plurality of signal terminals 50.

The package 10 is a member which protects each portion in the configuration of the current sensor 1; encapsulates a turn portion 43, a first body portion 42a, and a second body portion 42b in the conductor 40, the magnetic sensor 30, and a base end side of the plurality of signal terminals 50; and exposes a first terminal portion 41a and a second terminal portion 41b from one side (a lower side of the figure) of the vertical direction, and exposes edges of the plurality of signal terminals 50 from another side (an upper side of the figure) of the vertical direction. The package 10 is molded into a rectangular parallelepiped of a flat shape by mold forming, by using encapsulating resin with an excellent dielectric property, such as epoxy.

The magnetic sensor 30 is a sensor which detects the magnetic field that is generated by the current to be measured flowing through the conductor 40, and includes a substrate 31 and two sensor units 20. The magnetic sensor 30 is arranged on the conductor 40. It should be noted that the magnetic sensor 30 is set to include two sensor units 20, but instead of this, may include only one sensor unit.

The substrate 31 is a member of a plate shape which supports the two sensor units 20, and has a plurality of wirings (not shown) laid on an upper surface thereof. The substrate 31 is formed, for example, by using any of silicon (Si), gallium arsenide (GaAs), gallium nitride (GaN), aluminum nitride (AlN), sapphire (Si₂O₃), silicon carbide (SiC), or diamond.

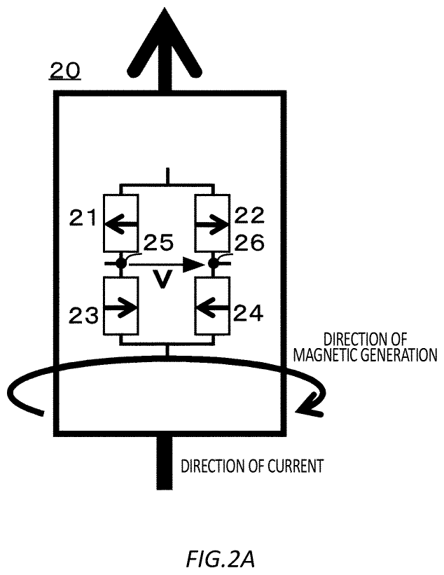

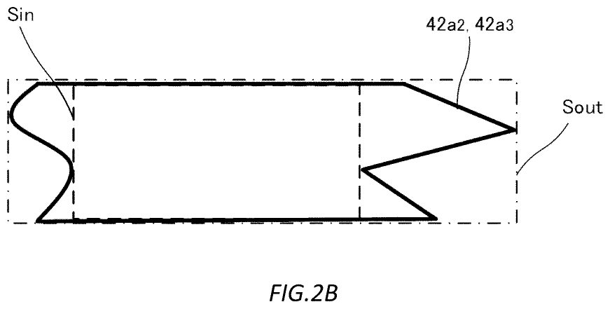

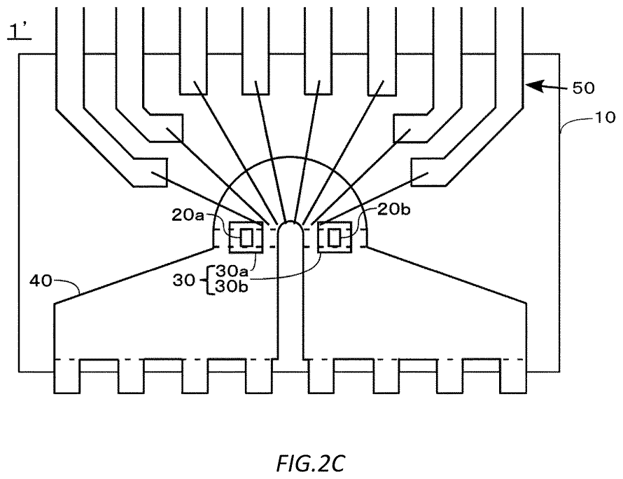

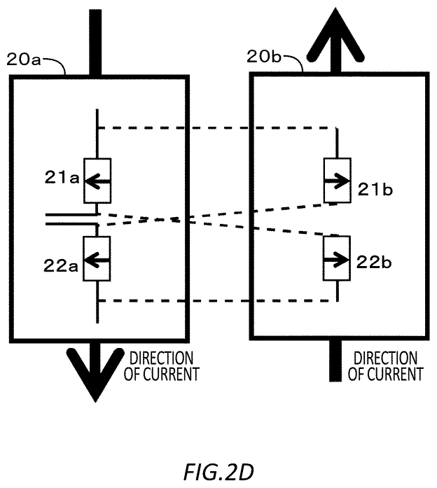

FIG. 2A shows a schematic configuration of a sensor unit 20. The sensor unit 20 is a circuit which changes an output voltage according to a magnetic flux density; and includes a plurality of (four in the present example) magnetoelectric conversion elements 21, 22, 23, 24 assembled in a shape of a Wheatstone ridge (full-bridge) circuit. It should be noted that the two magnetoelectric conversion elements 21 and 23, or the two magnetoelectric conversion elements 22 and 24 may be used to be assembled in a shape of a half-bridge circuit.

The plurality of magnetoelectric conversion elements 21, 22, 23, 24 are elements of which electrical characteristics (that is, magnetic resistances) change by a strength of the magnetic field that is applied. The magnetoelectric conversion elements 21, 22, 23, 24 are arranged with each of the magnetic sensitive directions being oriented toward a horizontal direction, so as to detect a horizontal magnetic field that is generated on the conductor 40 by the current to be measured flowing through the conductor 40 in a direction of an arrow. Note that the magnetic sensitive directions of the magnetoelectric conversion elements 21, 24 are the same direction as each other; and the magnetic sensitive directions of the magnetoelectric conversion elements 22, 23 are the same direction as each other, and are directions opposite to the magnetic sensitive directions of the magnetoelectric conversion elements 21, 24. As the plurality of magnetoelectric conversion elements 21, 22, 23, 24, it is possible to adopt any element of a tunnel magnetoresistance element (TMR), a giant magnetoresistance element (GMR), or an anisotropic magnetoresistance element (AMR). For these elements, it is possible to use alloys containing at least one of Co, Fe, B, Ni, or Si, and more specifically, cobalt iron (CoFe), cobalt iron boron (CoFeB), and nickel iron (NiFe). By using these elements, it is possible to precisely measure the current flowing through the conductor 40.

An output voltage V is a differential voltage between a terminal 25 between magnetoelectric conversion elements 21 and 23, and a terminal 26 between the magnetoelectric conversion elements 22 and 24; and magnetic resistances R1, R2, R3, R4 of the respective magnetoelectric conversion elements 21, 22, 23, 24 are used to establish V∝R1×R3−R2×R4. This makes it possible for the magnetic sensor 30 to measure the strength of the magnetic field generated by the current to be measured flowing through the conductor 40, and makes it possible to measure the current amount of the current to be measured.

The two sensor units 20 of the magnetic sensor 30 are respectively arranged in a connection portion (a first portion 421a of the first body portion 42a described below) between the first body portion 42a and the turn portion 43, and a connection portion (a first portion 421b of the second body portion 42b described below) between the second body portion 42b and the turn portion 43. These connection portions have rectangular shapes in a top plan view as described below, and the sensor unit 20 is arranged on top of them, thereby making it possible to concentrate, on the sensor unit 20, the magnetic field that is generated by energizing the conductor 40, and to detect the amount of current with high sensitivity. It should be noted that the connection portion may have a rectangular shape or an approximately rectangular shape in a top plan view.

FIG. 2B shows a definition of rectangularity that represents a degree to which a connection portion (the first portion 421a of the first body portion 42a or the first portion 421b of the second body portion 42b) has a rectangular shape. A contour of the connection portion is set to be represented by a solid line. For two parallel sides extending in the horizontal direction and two parallel sides extending in the vertical direction, which form a rectangular shape, the rectangularity Sin/Sout is defined by using an area Sin of a rectangular region with a greatest area that is arranged inside the contour of the connection portion, and an area Sout of a rectangular region with a smallest area that is arranged outside the contour of the connection portion. A true rectangular shape has rectangularity of 1, and an approximately rectangular shape has rectangularity of 0.8 or more and less than 1. By allowing the connection portion to have an approximately rectangular shape without being limited to the rectangular shape in a top plan view, it becomes easy to mold a lead frame when the conductor 40 is manufactured, and it becomes easy for the conductor 40 to be adhered to the package 10, and it is possible to prevent peeling off between them.

It should be noted that the sensor unit 20 may be configured by using a Hall element, and may be arranged inside the turn portion 43 or near the conductor 40 to detect a vertical magnetic field that is generated by the current flowing through the conductor 40.

FIG. 2C shows a configuration of the current sensor 1′ including two magnetic sensors 20a, 20b, in a top plan view. In the current sensor 1′, the magnetic sensor 30 may include a first magnetic sensor 30a which includes a sensor unit 20a, and a second magnetic sensor 30b which includes a sensor unit 20b; the sensor unit 20a of the first magnetic sensor 30a may be arranged on the connection portion (the first portion 421a of the first body portion 42a described below) between the first body portion 42a and the turn portion 43, and the sensor unit 20b of the second magnetic sensor 30b is arranged on the connection portion (the first portion 421b of the second body portion 42b described below) between the second body portion 42b and the turn portion 43; each of the first magnetic sensor 30a and the second magnetic sensor 30b may include a magnetoresistance element of any of a tunnel magnetoresistance element (TMR), a giant magnetoresistance element (GMR), or an anisotropic magnetoresistance element (AMR); and the first magnetic sensor 30a and the second magnetic sensor 30b may have magnetic sensitive directions opposite to each other, and may be connected to each other by wiring. Here, the Wheatstone ridge or the half-bridge circuit may be assembled by using magnetoresistance elements 21a and 22b, and 22a and 21b which are included in the sensor units 20a, 20b of the first magnetic sensor 30a and the second magnetic sensor 30b, and which have magnetic sensitive directions opposite to each other (refer to FIG. 2D). By assembling the Wheatstone ridge or the half-bridge circuit by using the magnetoresistance elements 21a and 22b, and 22a and 21b which are included in the first magnetic sensor 30a and the second magnetic sensor 30b, and which have magnetic sensitive directions opposite to each other, it is possible to suppress an increase in manufacturing cost more than a case of adopting a tunnel magnetoresistance element (TMR) or a giant magnetoresistance element (GMR) having sensitivity directions different from each other in one magnetic sensor 30.

The conductor (also referred to as a bus bar) 40 is a conductive member which forms a current path through which the current to be measured flows, and which has the first terminal portion 41a, the second terminal portion 41b, the first body portion 42a, the second body portion 42b, and the turn portion 43.

The first terminal portion 41a is a terminal for inputting the current to be measured (also simply referred to as the current). The first terminal portion 41a is arranged on one side (the lower side of the figure) in the vertical direction and includes a plurality of terminals 41a1, 41a2, 41a3, and 41a4 (four in the present example) which protrude from a side surface of the package 10 on the lower side of the figure.

The second terminal portion 41b is a terminal portion for outputting the current. The second terminal portion 41b is arranged to be separate from the first terminal portion 41a in the right direction in the figure, and includes a plurality of terminals 41b1, 41b2, 41b3, and 41b4 (four in the present example) which protrude from the side surface of the package 10 on the lower side of the figure. It should be noted that the second terminal portion 41b may be used as the terminal portion for inputting the current, and the first terminal portion 41a may be used as the terminal portion for outputting the current.

The first body portion 42a is a portion that connects one end of the turn portion 43 and the first terminal portion 41a. The first body portion 42a has a shape in which a cross sectional area is increased from the connection portion with the turn portion 43 toward a connection portion with the first terminal portion 41a; and has the first portion (also referred to as an arm portion, which is also the connection portion between the first body portion 42a and the turn portion 43) 421a and a second portion 422a. The first portion 421a is a portion that is connected to the turn portion 43 and has a rectangular shape in a top plan view. The second portion 422a is a portion that is connected to the terminal portion 41a and that is increased in width from the first portion 421a toward the first terminal portion 41a.

The second body portion 42b is a portion that connects another end of the turn portion 43 and the second terminal portion 41b, and is arranged to be separate from the first body portion 42a to the right in the figure. The second body portion 42b has a shape in which a cross sectional area is increased from the connection portion with the turn portion 43 toward a connection portion with the second terminal portion 41b; and has the first portion (also the connection portion between the second body portion 42b and the turn portion 43) 421b and the second portion 422b. The first portion 421b is a portion that is connected to the turn portion 43 and has a rectangular shape in a top plan view. The second portion 422b is a portion that is connected to the terminal portion 41b and that is increased in width from the first portion 421b toward the first terminal portion 41b.

The turn portion 43 is a portion that: is connected to the two body portions 42a, 42b at both ends; is arranged on another side (the upper side of the figure) in the vertical direction; extends from one side (the lower side of the figure) in the vertical direction to the another side (the upper side of the figure); has a shape of bending and returning to one side in the horizontal direction; and has an approximately circular arc shape, as an example. It should be noted that the turn portion 43 may be bent to have a U shape, an inverted V shape, or an n shape. In the turn portion 43, the current to be measured is input from the first body portion 42a, and the current to be measured is output to the second body portion 42b.

By including the first terminal portion 41a, the second terminal portion 41b, the first body portion 42a, the second body portion 42b, and the turn portion 43 which are formed as described above, the conductor 40 has an approximately U shape that: runs through an inside of the package 10, from the first terminal portion 41a provided on a left side of the figure, on the side surface of the package 10 on the lower side of the figure; returns to the lower side of the figure; and reaches to the second terminal portion 41b provided on a right side of the side surface on the lower side of the figure. It is possible to use conductive metal such as, for example, copper to form the conductor 40.

The plurality of signal terminals 50 are members for transmitting the output signal of the magnetic sensor 30 to a secondary circuit 3 (the details will be described below); are separated from the conductor 40 to the upper side of the figure; and are encapsulated in the package 10 with the edges being exposed from a side surface on the upper side of the figure. It is possible to use a conductive metal such as copper to form the plurality of signal terminals 50. The plurality of signal terminals 50 are bonded to the magnetic sensor 30 by wiring. It should be noted that an edge portion exposed from the package 10 is connected to the secondary circuit 3 on a mounting substrate 100 when the current sensor 30 is mounted on the mounting substrate 100.

The conductor 40 has electrical resistance that is slight though, and generates heat when the current flows through it. Here, when an instantaneous overcurrent, such as that which occurs during a failure, flows through the conductor 40, heat dissipation through the package is sufficiently slow and can be ignored, and thus a distribution AT of a temperature change in the conductor 40 is expressed by the following equation with respect to a position r on the conductor 40.

$$Δ T ( r ) = q ( r ) / c ( r ) \times Δ t \qquad ( 1 )$$

Here, q is an amount of heat generation per volume, c is heat capacity per volume, and At is a heating time. In a case where the conductor 40 has a material and a thickness that are uniform, c is constant regardless of the position r, and the temperature change AT is determined by Joule heating, that is, the current density. That is, which position r, a load due to the heat generation is applied to, is determined by the current density at the position r. Accordingly, when electrical resistivity in the conductor 40 is uniform, the current density is set by a cross sectional area of the conductor 40 along the current path, and the load due to the heat generation is concentrated on the position r on the current path with a small cross sectional area.

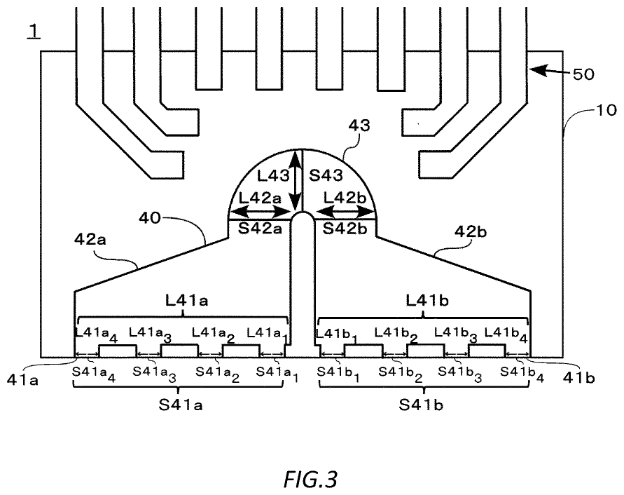

FIG. 3 shows definitions of cross sections S41a, S41b, S42a, S42b, S43 of the conductor 40. The cross section S41a is a cross section of the first terminal portion 41a, which is taken along the outer plane of the package 10, and includes cross sections S41a₁, S41a₂, S41a₃, S41a₄ of the plurality of terminals 41a₁, 41a₂, 41a₃, and 41a₄, respectively. The cross section S41b is a cross section of the second terminal portion 41b, which is taken along the outer plane of the package 10, and includes cross sections S41b₁, S41b₂, S41b₃, S41b₄ of the plurality of terminals 41b₁, 41b₂, 41b₃, and 41b₄, respectively. The cross section S42a is a cross section of the connection portion between the first body portion 42a and the turn portion 43. The cross section S42b is a cross section of the connection portion between the second body portion 42b and the turn portion 43. The cross section S43 is a cross section on the central axis of the conductor 40 parallel to the vertical direction in the turn portion 43. A cross sectional area of the turn portion 43 is given by the area of the cross section S43.

Here, at least one of a cross sectional area of the cross section S41a or a cross sectional area of the cross section S41b is set to be smaller than the cross sectional area of the cross section S43 of the turn portion 43. In this manner, when the magnetic field that is generated by energizing the conductor 40 is measured, by the magnetic sensor 30 arranged on the conductor 40, to detect the amount of current, even though the overcurrent flows, the current is concentrated on the connection portion between the first terminal portion 41a and the first body portion 42a, or the connection portion between the second terminal portion 41b and the second body portion 42b, which are close to an outer surface of the package 10, to cause a failure to occur, thereby making it easy to check for the failure in the current sensor 1 from an outside of the package 10.

In addition, at least one of a total of cross sectional areas of the cross sections S41a₁ to S41a₄, or a total of cross sectional areas of the cross sections S41b₁ to S41b₄ is set to be smaller than the cross sectional area of the turn portion 43. In this manner, by increasing the cross sectional areas of the first body portion 42a and the second body portion 42b to reduce the resistance, and decreasing the cross sectional areas of the first terminal portion 41a and the second terminal portion 41b, by including the plurality of terminals 41a₁ to 41a₄, and 41b₁ to 41b₄, to increase the resistance, even though the overcurrent flows, the current is concentrated on any terminal among the plurality of terminals 41a₁ to 41a₄, and 41b₁ to 41b₄ of the connection portion between the first terminal portion 41a and the first body portion 42a, and the connection portion between the second terminal portion 41b and the second body portion 42b, which are close to the outer surface of the package 10, to cause a failure to occur, thereby making it possible to check for the failure in the current sensor from the outside of the package 10.

In addition, at least one of the cross sectional area of the cross section S41a or the cross sectional area of the cross section S41b is set to be smaller than the cross sectional area of the cross section S42a of the connection portion between the turn portion 43 and the first body portion 42a, and the cross sectional area of the cross section S42b of the connection portion between the turn portion 43 and the second body portion 42b. In this manner, in comparison with the connection portion between the turn portion 43 and the first body portion 42a, and the connection portion between the turn portion 43 and the second body portion 42b, the current is concentrated more on at least one of the cross section S41a of the first terminal portion 41a, which is taken along the outer plane of the package 10, or the cross section S41b of the second terminal portion 41b, which is taken along the outer plane of the package 10, to increase the temperature and cause a failure to occur, thereby making it easy to check for the failure of the current sensor from the outside of the package 10.

Here, when the overcurrent flows instantaneously through the conductor 40 to a degree that the current is concentrated on at least one of the cross sections S41b to increase the temperature and cause a failure to occur, the current is easily concentrated near the turn portion 43. That is, when the overcurrent flows instantaneously through the conductor 40, the current is easily concentrated near the turn portion 43, next to the first terminal portion 41a outside the package 10, and the temperature easily becomes high. In the present invention, the sensor unit 20 is arranged not on the turn portion 43, but in the connection portion (the first portion 421a of the first body portion 42a described below) between the first body portion 42a and the turn portion 43, and the connection portion (the first portion 421b of the second body portion 42b described below) between the second body portion 42b and the turn portion 43, thereby making it possible to prevent a thermal destruction of the sensor in the event of a failure occurrence and detect the amount of current with high sensitivity.

FIG. 3 further shows definitions of a width L41a, a width L41b, a width L42a, a width L42b, and a width L43 of the conductor 40. The width L41a is a width of the cross section S41a of the first terminal portion 41a, which is taken along the outer plane of the package 10, and is a total sum of respective widths L41a₁, L41a₂, L41a₃, and L41a₄ of the plurality of terminals 41a₁, 41a₂, 41a₃, and 41a₄. The width L41b is a width of the cross section S41b of the second terminal portion 41b, which is taken along the outer plane of the package 10, and is a total sum of respective widths L41b₁, L41b₂, L41b₃, and L41b₄ of the plurality of terminals 41b₁, 41b₂, 41b₃, and 41b₄. The width L42a is a width of the connection portion between the first body portion 42a and the turn portion 43. The width L42b is a width of the connection portion between the second body portion 42b and the turn portion 43. The width L43 is a width on the central axis of the conductor 40 parallel to the vertical direction in the turn portion 43.

Here, the thickness of the conductor 40 is approximately constant, and at least one of the width L41a of a cross section S41a of the first terminal portion 41a, which is taken along the outer plane of the package 10, or the width L41b of a cross section S41b of the second terminal portion 41b, which is taken along the outer plane of the package 10, is set to be smaller than the width L43 of the turn portion 43. In this manner, when the plate thickness is approximately constant, at least one of the cross sectional area of the cross section S41a of the first terminal portion 41a, which is taken along the outer plane of the package 10, or the cross sectional area of the cross section S41b of the second terminal portion 41b, which is taken along the outer plane of the package 10, becomes smaller than the cross sectional area of the cross section S43 of the turn portion 43, and thus it is possible to set a configuration in which not in the turn portion 43, but in the first terminal portion 41a or the second terminal portion 41b, it is possible to check for a failure.

In addition, at least one of the width L41a of the cross section S41a of the first terminal portion 41a, which is taken along the outer plane of the package 10, or the width L41b of the cross section S41b of the second terminal portion 41b, which is taken along the outer plane of the package 10, is further set to be smaller than the width L42a of the connection portion between the first body portion 42a and the turn portion 43, and the width L42b of the connection portion between the second body portion 42b and the turn portion 43. In this manner, when the plate thickness is constant, at least one of the cross sectional area of the cross section S41a of the first terminal portion 41a, which is taken along the outer plane of the package 10, or the cross sectional area of the cross section S41b of the second terminal portion 41b, which is taken along the outer plane of the package 10, becomes smaller than the cross sectional area of the cross section S42a of the connection portion between the turn portion 43 and the first body portion 42a, and the cross sectional area of the cross section S42b of the connection portion between the turn portion 43 and the second body portion 42b, and it is possible to set a configuration in which not in the turn portion 43, the connection portion between the first body portion 42a and the turn portion 43, or the connection portion between the second body portion 42b and the turn portion 43, but in the first terminal portion 41a or the second terminal portion 41b, it is possible to check for a failure.

The current to be measured flowing through the conductor 40 is not limited to a direct current, and may be an alternating current. When the current to be measured is the alternating current, a skin effect occurs in the conductor 40. The skin effect is a phenomenon in which, when the alternating current flows through the conductor 40, the higher the frequency of the current is, the more the current is concentrated near the surface of the conductor 40, and the further away from the surface of conductor 40, the more difficult it is for the current to flow, and the temperature inside the conductor 40 rises. Accordingly, for each portion of the conductor 40, by increasing a ratio of a surface area with respect to the cross sectional area, it is possible to prevent the resistance of each portion from increasing even when the skin effect occurs due to a high frequency current.

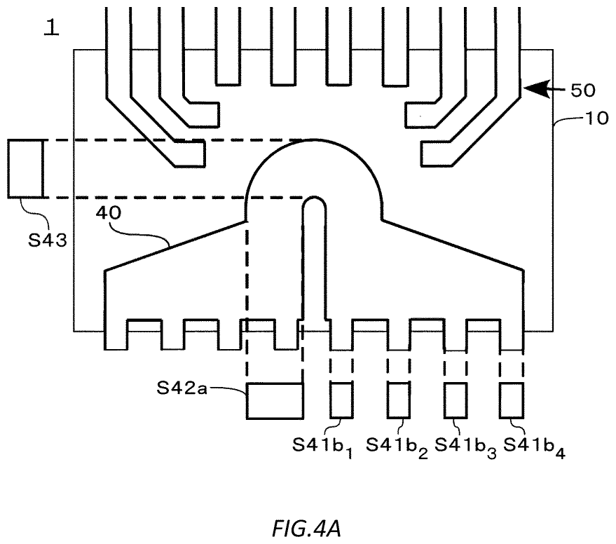

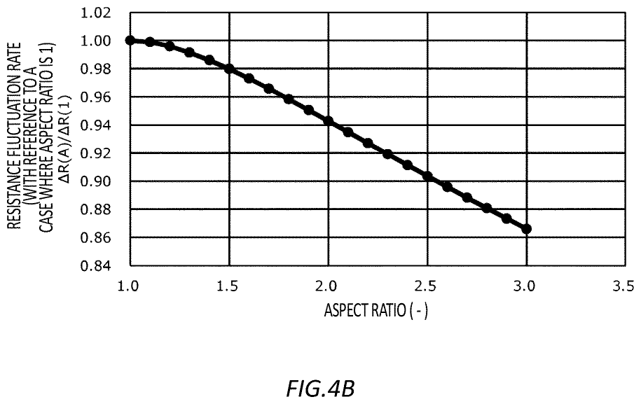

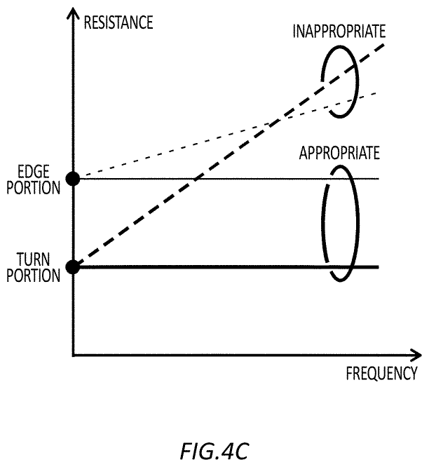

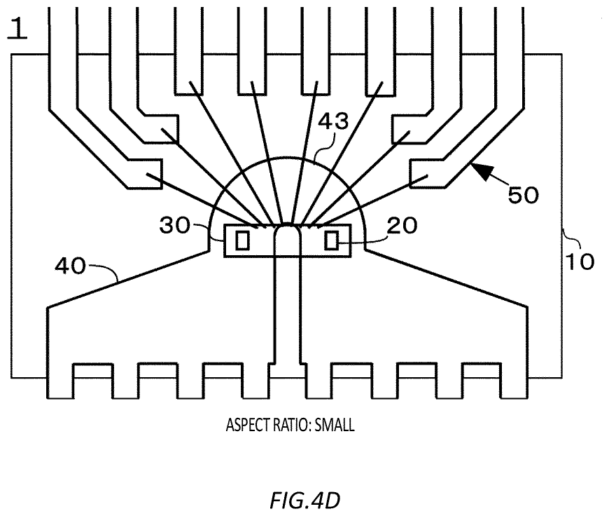

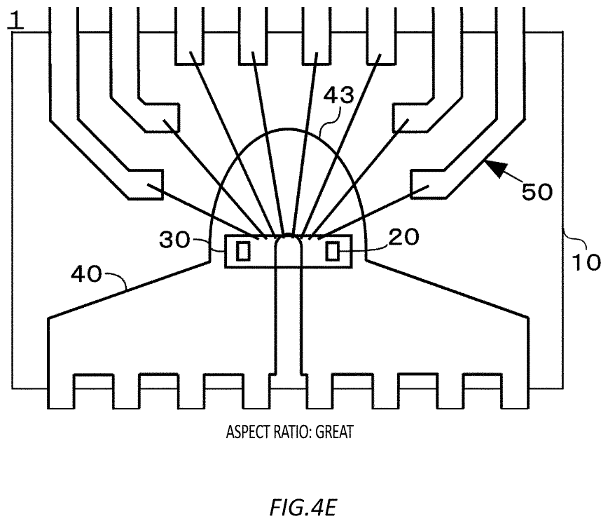

FIG. 4A shows definitions of cross sections S43, S41a, S41b, S42a, and S42b of the conductor 40.

FIG. 4B shows a relationship between an aspect ratio, and a resistance fluctuation rate due to the skin effect with reference to a case where the aspect ratio is 1, when the cross section of the conductor 40 has a rectangular shape and the aspect ratio is set to be a long side/a short side. When the conductor is formed of copper, the skin depth δ (unit: mm) is δ=75/√f. Here, f is the frequency of the current (unit: Hz). On an assumption of the cross section with a short side t and a long side W, a resistance R(0) and a resistance R(f) with respect to the direct current and the alternating current of frequency f are R(0)∝1/(t×W) and R(f)∴1/(2(t+W) δ). Accordingly, an increase rate in resistance due to the skin effect of a rectangular cross section (the aspect ratio A=W/t) with the short side t and the long side W, is ΔR(A)=R(f)/R(0)=(t×W)/(2(t+W)δ). When the cross sectional area t×W=S is constant, it can be written as t=√(S/A), and W=√(S×A), and thus a fluctuation rate of the increase in resistance due to the skin effect with reference to a case where the aspect ratio=1, is ΔR(A)/ΔR(1)=(2(√(S/1)+√(S×1)δ)/(2(√(S/A)+√(S×A)δ)=2/(1/√A+√A). Accordingly, by increasing the aspect ratio from 1 with respect to the same cross sectional area, it is possible to suppress the increase in resistance due to the skin effect.

The cross section S43 is the cross section of the conductor 40 in the turn portion 43. The length of the short side of the cross section S43 is equal to the thickness of the conductor 40, and the length of the long side is equal to the width L43 of the turn portion 43. When the thickness of the conductor 40 is approximately constant, the length of the short side of the cross section S43 is equal to the lengths of the short sides of the cross sections S42a, S42b, and the lengths of the long sides of the cross sections S41a₁ to S41a₄, and S41b₁ to S41b₄. With respect to the long side and the short side of the cross section of the rectangular shape, when the long side/the short side is set to be the aspect ratio, the aspect ratio of the cross section S43 is 1.4 to 2.7. Even for the alternating current by which the skin effect occurs, by increasing the surface area with respect to the area of the turn portion 43, without increasing the resistance in the turn portion 43, it is possible to suppress the temperature change more than in the first terminal portion 41a or the second terminal portion 41b. It should be noted that by setting the aspect ratio of the cross section S43 to 1.4, it is possible to reduce the increase rate in resistance due to the skin effect by 1%. More preferably, by setting the aspect ratio to 2.0, it is possible to reduce the increase rate in resistance due to the skin effect by 6%. Further more preferably, by setting the aspect ratio to 2.5, it is possible to reduce the increase rate in resistance due to the skin effect by 10%. Note that setting the aspect ratio to be greater than 2.7, increases a package size, and the difficulty of a process, and thus is not preferable.

As described above, the cross section S41a is a cross section of the conductor 40 at the first terminal portion 41a, which is taken along the outer plane of the package 10 (refer to FIG. 3). The lengths of the short sides of the cross sections S41a₁, S41a₂, S41a₃, S41a₄ of the plurality of terminals 41a₁, 41a₂, 41a₃, 41a₄ are respectively equal to the widths L41a₁ to L41a₄ of the plurality of terminals 41a₁ to 41a₄ in a top plan view, and the length of the long side is equal to the thickness of the conductor 40. When the thickness of the conductor 40 is approximately constant, the long sides of the cross sections S41a₁ to S41a₄ are equal in length to the short sides of the cross sections S43, S42a, and S42b, and the long sides of the cross sections S41b₁ to S41b₄.

As described above, the cross section S41b is a cross section of the conductor 40 at the second terminal portion 41b, which is taken along the outer plane of the package 10. The lengths of the short sides of the cross sections S41b₁, S41b₂, S41b₃, S41b₄ of the plurality of terminals 41b₁, 41b₂, 41b₃, 41b₄ are respectively equal to the widths L41b₁ to L41b₄ of the plurality of terminals 41b₁ to 41b₄ in a top plan view, and the length of the long side is equal to the thickness of the conductor 40. When the thickness of the conductor 40 is approximately constant, the long sides of the cross sections S41b₁ to S41b₄ are equal in length to the short sides of the cross sections S43, S42a, and S42b and the long sides of the cross sections S41a₁ to S41a₄.

By the aspect ratios in the cross section S41a and the cross section S41b being both 1.4 to 2.7, the surface areas with respect to the areas of the first terminal portion 41a and the second terminal portion 41b are increased, and for the alternating current by which the skin effect occurs, without increasing the resistance in the first terminal portion 41a and the second terminal portion 41b, it is possible to prevent the first terminal portion 41a or the second terminal portion 41b from becoming excessively susceptible to a failure. It should be noted that by setting the aspect ratios of the cross sections S41a₁ to S41a₄ and S41b₁ to S41b₄ to 1.4, it is possible to reduce the increase rate in resistance due to the skin effect by 1%. More preferably, by setting the aspect ratio to 2.0, it is possible to reduce the increase rate in resistance due to the skin effect by 6%. Further more preferably, by setting the aspect ratio to 2.5, it is possible to reduce the increase rate in resistance due to the skin effect by 10%. Note that setting the aspect ratio to be greater than 2.7, increases the package size, and the difficulty of the process, and thus is not preferable.

As described above, the cross section S42a is a cross section of the conductor 40, at the connection portion between the first body portion 42a and the turn portion 43. The length of the short side of the cross section S42a is equal to the thickness of the conductor 40, and the length of the long side is equal to the width L42a of the connection portion between the turn portion 43 and the first body portion 42a. When the thickness of the conductor 40 is approximately constant, the length of the short side of the cross section S42a is equal to the lengths of the short sides of the cross sections S43, S42b, and the lengths of the long sides of the cross sections S41a₁ to S41a₄, and S41b₁ to S41b₄.

As described above, the cross section S42b is a cross section of the conductor 40, at the connection portion between the second body portion 42b and the turn portion 43 (refer to FIG. 3). The length of the short side of the cross section S42b is equal to the thickness of the conductor 40, and the length of the long side is equal to the width L42b of the connection portion between the turn portion 43 and the second body portion 42b. When the thickness of the conductor 40 is approximately constant, the short side of the cross section S42b is equal in length to the short sides of the cross sections S43 and S42a, and the long sides of the cross sections S41a₁ to S41a₄, and S41b₁ to S41b₄.

By the aspect ratios in the cross sections S42a, S42b being both 1.4 to 2.7, the surface areas with respect to the areas of the connection portions between the first body portion 42a and the turn portion 43, and between the second body portion 42b and the turn portion 43, are increased, even for the alternating current by which the skin effect of the cross section S42b occurs, without increasing the resistance in the turn portion 43, the first body portion 42a, or the second body portion 42b, it is possible to suppress the temperature change more than in the first terminal portion 41a or the second terminal portion 41b. Note that when the aspect ratios of the cross sections S42a, S42b are less than 1.4, it is not possible to sufficiently prevent the increase in resistance due to the skin effect, and at a time of exceeding 2.7, it is not possible to reduce a size of the current sensor 1 to secure the dielectric breakdown voltage between the first portion 421 of the body portion and the signal terminal 50.

FIG. 4C shows a relationship between a resistance and a frequency in the conductor 40. The solid line indicates the relationship between the resistance and the frequency when the ratio of the surface area with respect to the cross sectional area, for each portion of the conductor 40, is high, and as described above, even though the frequency is increased and the skin effect occurs, the resistance is not increased significantly. The dashed line indicates the relationship between the resistance and the frequency when the ratio of the surface area with respect to the cross sectional area, for each portion of the conductor 40, is low, and as described above, when the frequency is increased, the skin effect occurs, thereby increasing the resistance. The thick line indicates the relationship between the resistance and the frequency in the turn portion 43 of the conductor 40. The thin line indicates the relationship between the resistance and the frequency in the terminal portions 41a, 41b in the turn portion 43 of the conductor 40, which is the relationship between the resistance and the frequency. By increasing the ratio of the surface area with respect to the cross sectional area, for each portion of the conductor 40, it is possible to suppress the increase in resistance with respect to the frequency. It is difficult for the resistances of the turn portion 43 and the terminal portions 41a, 41b to be increased by the frequency, thereby making it possible to suppress a failure of each portion of the conductor 40 even when the alternating current of the high frequency flows as an overcurrent.

FIG. 4D and FIG. 4E show the current sensors in which the aspect ratios of the cross section S43 of the turn portion 43 are different from each other in top plan views. When the aspect ratio of the turn portion 43 is increased, the width of the turn portion 43 becomes great, in a case where the size of the package 10 is not changed, a separation distance between the turn portion 43 and the signal terminal 50 becomes smaller, and thus it is not possible to secure the dielectric breakdown voltage between the turn portion 43 and the signal terminal 50. Accordingly, when the aspect ratio of the turn portion 43 is increased, in order to maintain the separation distance between the turn portion 43 and the signal terminal 50 and secure the dielectric breakdown voltage, the package 10 becomes large and the current sensor 1 becomes large.

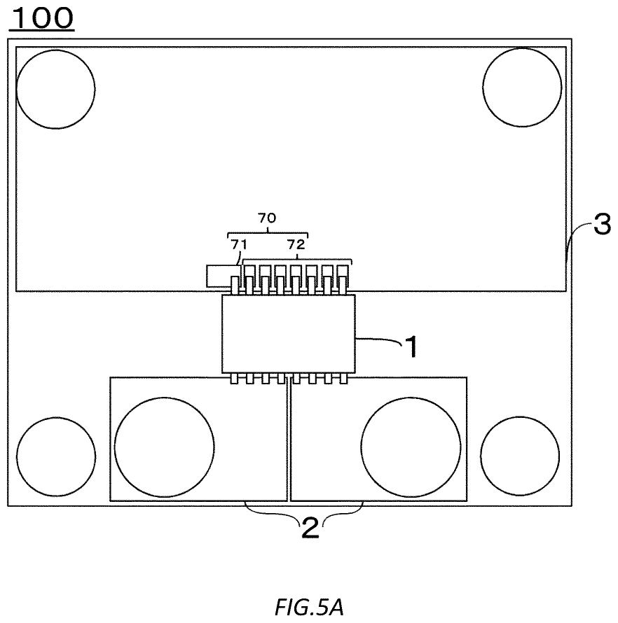

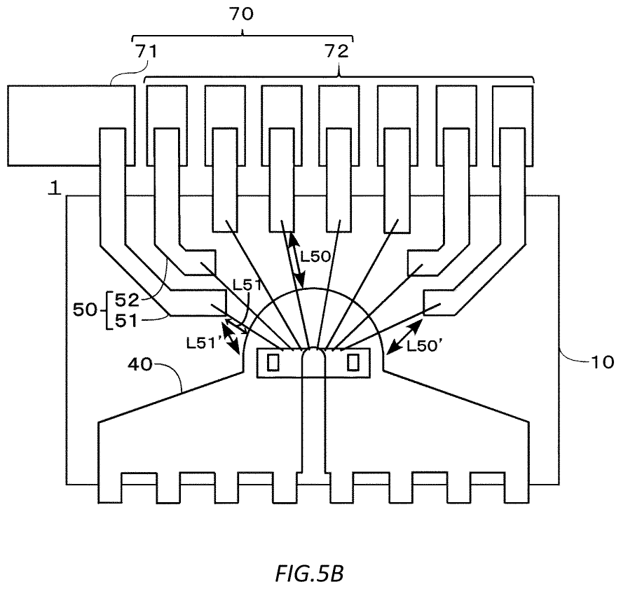

FIG. 5A shows a configuration of the mounting substrate 100 on which the current sensor 1 is mounted, in a top plan view. The mounting substrate 100 is a substrate including the current sensor 1, a primary circuit 2, and the secondary circuit 3. In the mounting substrate 100, the current to be measured is input from the primary circuit 2 to the current sensor 1, and the output signal of the current sensor 1 is output to the secondary circuit 3. It should be noted that the current sensor 1 is configured as described above.

The primary circuit 2 is a circuit which inputs the current to be measured to the current sensor 1, and is connected to the first terminal portion 41a and the second terminal portion 41b of the conductor 40 of the current sensor 1.

The secondary circuit 3 is a circuit which is operated in response to the output signal of the current sensor 1, and includes a plurality of footprints 70 that are respectively connected to a plurality of circuits (not shown). The plurality of footprints 70 are respectively connected to the plurality of signal terminals 50 (refer to FIG. 5B), and the output signal of the current sensor 1 is transmitted via the plurality of signal terminals 50 to each of the plurality of circuits. The plurality of footprints 70 include a footprint 71 and a footprint 72.

The footprint 71 is at least one footprint of the plurality of footprints 70, and is connected to a signal terminal 51 of the plurality of signal terminals 50 (refer to FIG. 5B).

The footprint 72 is a remaining footprint among the plurality of footprints 70 excluding the footprint 71, and is connected to a signal terminal 52 among the plurality of signal terminals 50 (refer to FIG. 5B).

FIG. 5B shows the arrangement of the current sensor 1 and the plurality of footprints 70 and the definitions of distances L51, L51′, L50, L50′, in a top plan view. As described above, the signal terminal 51 and the signal terminal 52 (refer to FIG. 5B) of the plurality of signal terminals 50 are respectively connected to the footprint 71 and the footprint 72 among the plurality of footprints 70. The distance L51 is a separation distance between the signal terminal 51 and the turn portion 43 of the conductor 40. The distance L51′ is a separation distance between the signal terminal 51 and the body portion 42 of the conductor 40. The distance L50 is a separation distance between another signal terminal 52 and the turn portion 43 of the conductor 40. The distance L50 may be a minimum value of the separation distance between each of other signal terminals 52 and the turn portion 43. The distance L50′ is a separation distance between each of the other signal terminals 52, and the body portions 42a, 42b of the conductor 40. The distance L50′ may be a minimum value of the separation distance between each of the other signal terminals 52, and the body portions 42a, 42b.

In the arrangement described above, the distance L51 is shorter in comparison with the distance L50. In other words, the signal terminal 51 is closer to the turn portion 43 than another signal terminal 52. This makes it possible for the heat generated in the turn portion 43 to be dissipated to the outside of the package 10, via the signal terminal 51 which is close to the turn portion 43 among the plurality of signal terminals 50. The distance L51 between the turn portion 43 and the signal terminal 51 is preferably 0.4 mm or more to ensure the insulation. It should be noted that the signal terminal 51 may be a GND terminal. By the signal terminal 51 close to the turn portion 43 being the GND terminal, when an electric arc occurs in the turn portion 43, it is possible to induce the discharge of the electricity from the close signal terminal 51 to the GND, thereby suppressing the damage to the plurality of circuits on the secondary circuit 3 to which another signal terminal 52 is connected.

Further, the distance L51 is shorter than the distance L50, and the distance L51′ is shorter than the distance L50′. In other words, the signal terminal 51 is closer to any of the turn portion 43, and the first body portion 42a or the second body portion 42b than another signal terminal 52 that is included in the plurality of signal terminals 50. In this manner, by the signal terminal 51 which is closest to the turn portion 43, the first body portion 42a, and the second body portion 42b, being the GND terminals, when an electric arc occurs in the turn portion 43 and the body portion 42, it is possible to induce the discharge of the electricity from the close signal terminal 51 to the GND, thereby suppressing the damage to the plurality of circuits on the secondary circuit 3 to which another signal terminal 52 is connected.

When the current 1 sensor is mounted on the mounting substrate 100, the signal terminal 51 is connected to the footprint 71, on the mounting substrate 100, which has a greater area than the footprint 72 to which another signal terminal 52 is connected. In this manner, by connecting the signal terminal 51 to the footprint 71, on the mounting substrate, which has a greater area than the footprint 72 to which another signal terminal 52 is connected, it is possible for the signal terminal 51, to which the heat is transferred from the turn portion 43, to have a greater heat dissipation area and dissipate the heat efficiently, and it is possible to enhance a heat dissipation property of the turn portion 43 and prevent a failure due to the heat accumulation. The footprint 71 preferably has an area 1.5 to 40 times that of another footprint 72.

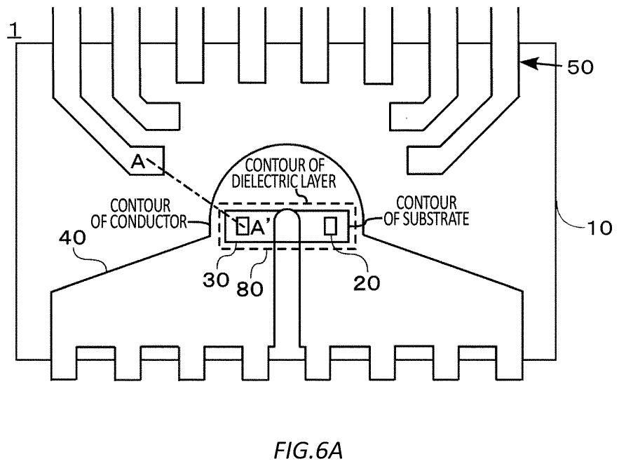

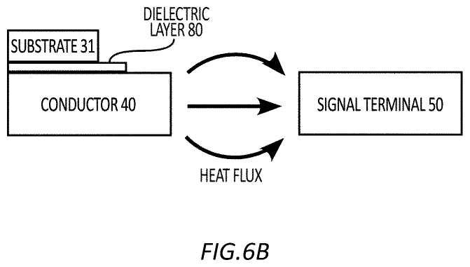

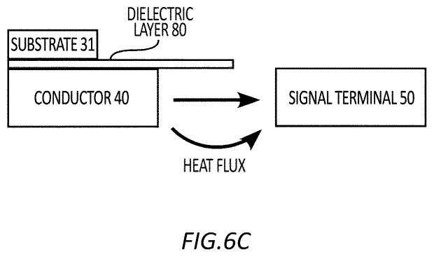

FIG. 6A shows an arrangement of the conductor 40, a dielectric layer 80, and the magnetic sensor 30, in a top plan view. The dielectric layer 80 is a member which insulates and protects the magnetic sensor 30 from the conductor 40, and is disposed between the conductor 40 and the magnetic sensor 30. It is possible to form the dielectric layer 80 by using, for example, a polyimide layer, glass, paper, Teflon (registered trademark), or silicon.

The magnetic sensor 30 is arranged on the conductor 40 via the dielectric layer 80, and a contour of the dielectric layer 80 is positioned between a contour of the magnetic sensor 30 and an outer contour of the conductor 40. In order to ensure the insulation, the contour of the dielectric layer 80 preferably has a distance of 0.4 mm or more from the contour of the magnetic sensor 30 to the outside. In this manner, the dielectric layer 80 insulates the magnetic sensor 30 from the conductor 40 without covering the entire upper surface of the conductor 40, and the dielectric layer 80 does not impede the heat dissipation of the conductor 40 and does not reduce the heat dissipation property of the conductor 40.

FIG. 6B and FIG. 6C show arrangements of the conductor 40, the dielectric layer 80, and the magnetic sensor 30 at the cross section A-A′ of FIG. 6A, in side views. As shown in FIG. 6B, when the contour of the dielectric layer 80 is positioned between the contour of the magnetic sensor 30 and the outer contour of the conductor 40, it is possible for the conductor 40 to have a heat dissipation surface without the dielectric layer 80 covering the entire upper surface of the conductor 40. On the other hand, as shown in FIG. 6C, when the contour of the dielectric layer 80 is positioned outside the contour of the magnetic sensor 30 and the outer contour of the conductor 40, the dielectric layer 80 covers the conductor 40, and it is not possible for the conductor 40 to secure a sufficiently large heat dissipation surface, thereby impeding the heat dissipation.

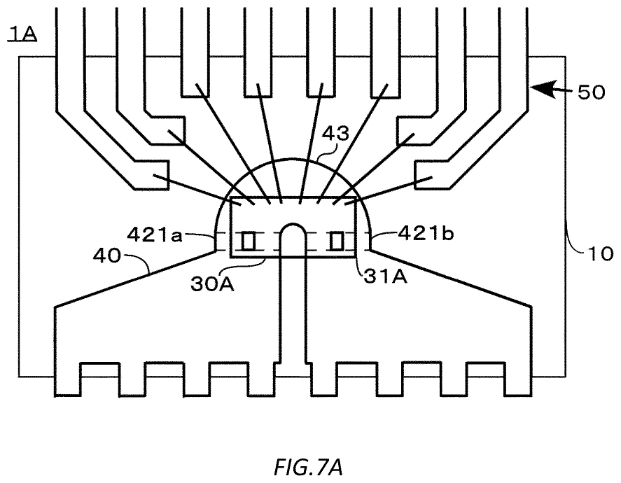

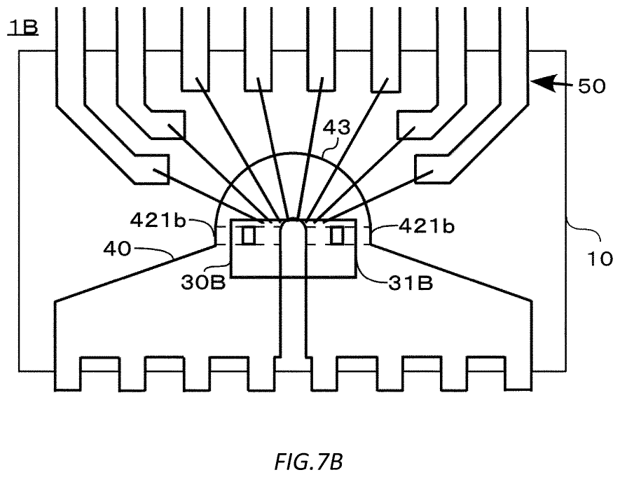

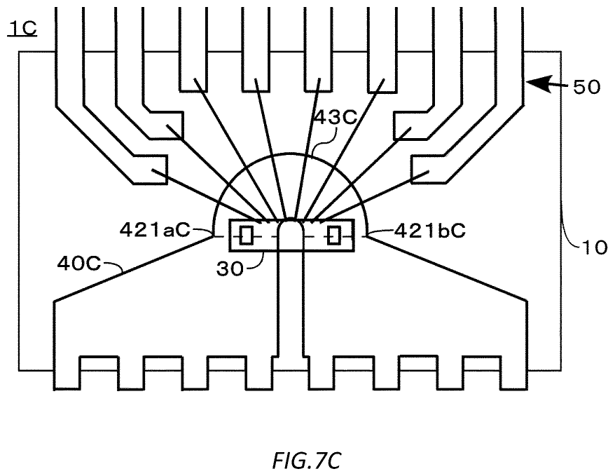

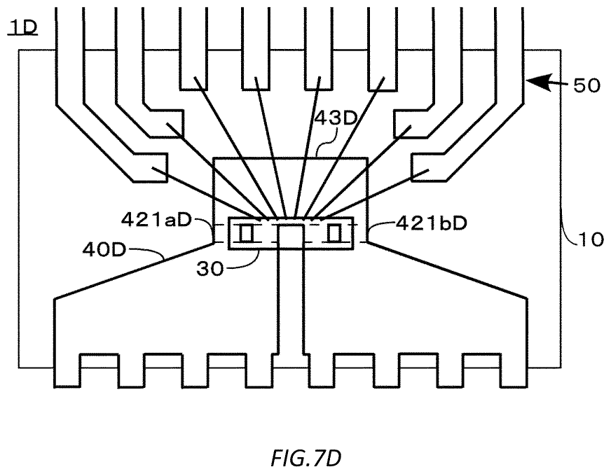

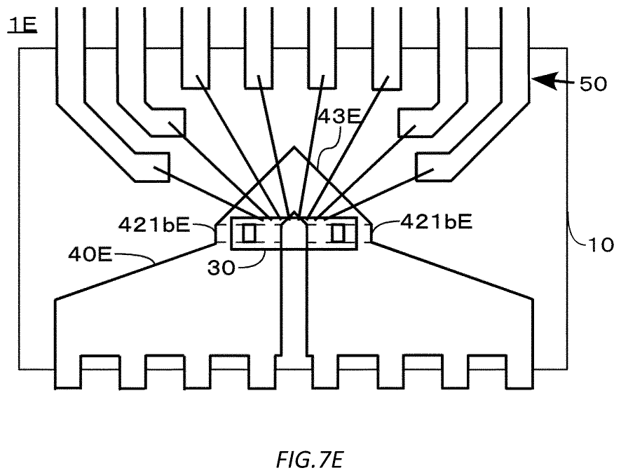

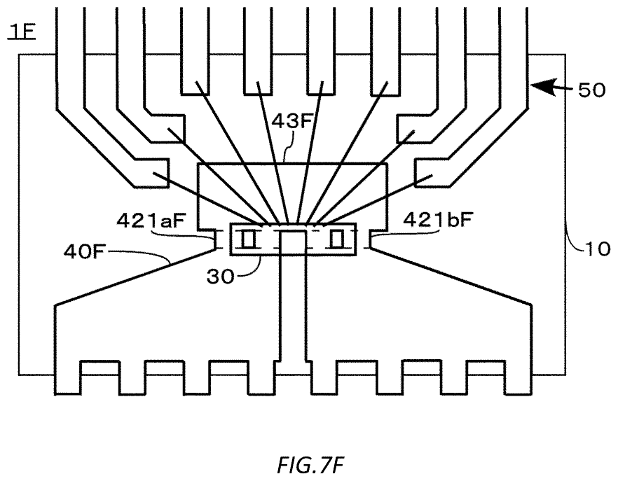

FIG. 7A to FIG. 7F show configurations of current sensors 1A, 1B, 1C, 1D, 1E, and 1F in respective modified examples, in top plan views.

FIG. 7A shows the configuration of the current sensor 1A according to a first modified example. It should be noted that signs and numerals for the configuration common to those in FIG. 1 are omitted. The current sensor 1A includes: the turn portion 43 of an inverted U shape, and the first portions 421a, 421b of the body portion; and a magnetic sensor 30A which is disposed on the first portions 421a, 421b of the body portion, and in which a substrate 31A extends onto the turn portion 43, and a vertical width of the substrate 31A is longer than the lengths of the first portions 421a, 421b of the body portion. By extending the substrate of the magnetic sensor 30A onto the turn portion 43, the substrate is brought close to the signal terminal 50, and the wire bonding of the signal terminal 50 becomes easy and manufacturability is enhanced.

FIG. 7B shows the configuration of the current sensor 1B according to a second modified example. It should be noted that signs and numerals for the configuration common to those in FIG. 1 are omitted. The current sensor 1B includes: the turn portion 43 of an inverted U shape, and the first portions 421a, 421b of the body portion; and a magnetic sensor 30B which is disposed on the first portions 421a, 421b of the body portion, and in which a substrate 31B extends onto the second portions 422a, 422b of the body portion, and a vertical width of the substrate 31B is longer than the lengths of the first portions 421a, 421b of the body portion. By extending the substrate 31B of the magnetic sensor 30B onto the second portion 422 of the body portion, the substrate becomes distant from the turn portion 43 which is a heat generating place, and thus it is possible to suppress the temperature rise of the substrate 31B of the magnetic sensor 30B, and the reliability of the current measurement is enhanced.

FIG. 7C shows the configuration of the current sensor 1C according to a third modified example. It should be noted that signs and numerals for the configuration common to those in FIG. 1 are omitted. The current sensor 1C includes: first portions 421aC, 421bC of the body portion which are shortened as much as possible to be shorter in length than the substrate 30; a turn portion 43C of an approximately circular arc shape; and the magnetic sensor 30 which spans the shortened first portions 421aC, 421bC of the body portion. By shortening the first portions 421aC, 421bC of the body portion as much as possible, it is possible to reduce the resistance of a conductor 40C and suppress the temperature change. By connecting the turn portion 43C to a place where the flow path from second portions 422aC, 422bC of the body portion is narrowest, and by increasing the current density and aligning the current in the vertical direction, it is possible to strengthen the magnetic field generated by the current to be measured, and it is possible to obtain the same function as those of the first portions 421aC, 421bC of the body portion in the dashed line portion in the figure.

FIG. 7D shows the configuration of the current sensor 1D according to a fourth modified example. It should be noted that signs and numerals for the configuration common to those in FIG. 1 are omitted. The current sensor 1D includes: a turn portion 43D of a U shape, and first portions 421aD, 421bD of the body portion; and the magnetic sensor 30 on the first portions 421aD, 421bD of the body portion. By forming the turn portion 43D and the first portions 421aD, 421bD of the body portion in a U shape, the process of the conductor 40D becomes easy, and the design of the signal terminal 50 also becomes easy.

FIG. 7E shows the configuration of the current sensor 1E according to a fifth modified example. It should be noted that signs and numerals for the configuration common to those in FIG. 1 are omitted. The current sensor 1E includes: a turn portion 43E of an inverted V shape, and first portions 421aE, 421bE of the body portion; and the magnetic sensor 30 on the first portions 421aE, 421bE of the body portion. By forming the turn portion 43E and the first portions 421aE, 421bE of the body portion in an inverted V shape, it is possible to design the turn portion 43E to be small in size.

FIG. 7F shows the configuration of the current sensor 1F according to a sixth modified example. It should be noted that signs and numerals for the configuration common to those in FIG. 1 are omitted. The current sensor 1F includes: a turn portion 43F of an n shape, and a first portion 421F of the body portion; and the magnetic sensor 30 on first portions 421aF, 421bF of the body portion. By forming the turn portion 43F and the first portions 421aF, 421bF of the body portion in an n shape, it is possible to widen the area of the turn portion 43F in a top plan view, and it is possible to enhance the heat dissipation property of the turn portion 43F.

As described above, the current sensor 1 according to the present embodiment includes: the conductor 40 having the first terminal portion 41a inputting the current and the second terminal portion 41b for outputting the current which are arranged on one side in a first axial direction, the second terminal portion 41b being separated from the first terminal portion 41a in a second axial direction intersecting the first axial direction, the turn portion 43 which is arranged on another side in the first axial direction, the first body portion 42a which connects one end of the turn portion and the first terminal portion 41a, and the second body portion 42b which is separated from the first body portion 42a in the second axial direction, to connect another end of the turn portion 43 and the second terminal portion 41b; the magnetic sensor 30 which is arranged on the conductor 40 or near the conductor 40; and the package 10 which encapsulates the turn portion 43, the first body portion 42a, the second body portion 42b of the conductor 40, and the magnetic sensor 30, and which exposes the first terminal portion 41a and the second terminal portion 41b, in which at least one of an area of the cross section S41a of the first terminal portion 41a, which is taken along the outer plane of the package 10, or an area of the cross section S41b of the second terminal portion 41b, which is taken along the outer plane of the package 10, is smaller than the area of the cross section S43 of the turn portion 43. With this, by the area of each of the cross sections S41a, S41b of the first terminal portion 41a and the second terminal portion 41b of the conductor 40, which are close to the outer surface of the package 10, being smaller than the area of the cross section S43 of the turn portion 43 which is arranged inside the package 10, when the magnetic field that is generated by energizing the conductor 40 is measured by the magnetic sensor 30 arranged on or near the conductor 40 to detect the amount of current, even though the overcurrent flows, the current is concentrated on the first terminal portion 41a or/and the second terminal portion 41b, which are close to the outer surface of the package 10, to cause a failure to occur, thereby making it easy to check for the failure in the current sensor 1 from the outside of the package 10.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the description of the claims that the form to which such alterations or improvements are made can be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is described by using phrases such as “first” or “next” for the sake of convenience in the claims, specification, and drawings, it does not necessarily mean that the process must be performed in this order.

### EXPLANATION OF REFERENCES

1, 1′, 1A, 1B, 1C, 1D, 1E, 1F, 1G: current sensor; 2: primary circuit; 3: secondary circuit; 10: package; 20, 20a, 20b: sensor unit, 21, 22, 23, 24, 21a, 21b, 22a, 22b: magnetoelectric conversion element; 25, 26: terminal; 30, 30a, 30b: magnetic sensor; 31, 31A, 31B: substrate; 40: conductor; 41a, 41b: terminal portion; 41a₁, 41a₂, 41a₃, 41a₄, 41b₁, 41b₂, 41b₃, 41b₄: terminal; 42a, 42b: body portion; 421a, 421b: first portion of body portion; 422a, 422b: second portion of body portion; 43: turn portion; 50, 51, 52: signal terminal; 70, 71, 72: footprint; 80: dielectric layer; 100: mounting substrate; L41a, L41a₁, L41a₂, L41a₃, L41a₄, L41b, L41b₁, L41b₂, L41b₃, L41b₄, L42a, L42b, L43: width; L50, L50′, L51, L51′: distance; S41a, S41a₁, S41a₂, S41a₃, S41a₄, S41b, S41b₁, S41b₂, S41b₃, S41b₄, S42a, S42b, S43: cross section.

What is claimed is:

1. A current sensor comprising:
a conductor having
a first terminal portion for inputting a current and a second terminal portion for outputting the current which are arranged on one side in a first axial direction, the second terminal portion being separated from the first terminal portion in a second axial direction intersecting the first axial direction,
a turn portion which is arranged on another side in the first axial direction,
a first body portion which connects one end of the turn portion and the first terminal portion, and
a second body portion which is separated from the first body portion in the second axial direction, to connect another end of the turn portion and the second terminal portion;
a magnetic sensor which is arranged on the conductor or near the conductor; and
a package which encapsulates the turn portion, the first body portion, and the second body portion of the conductor, and the magnetic sensor, and which exposes the first terminal portion and the second terminal portion, wherein
at least one of a cross sectional area of a cross section of the first terminal portion, which is taken along an outer plane of the package, or a cross sectional area of a cross section of the second terminal portion, which is taken along the outer plane of the package, is smaller than a cross sectional area of the turn portion,
a connection portion between the first body portion and the turn portion, and a connection portion between the second body portion and the turn portion, have an approximately rectangular shape in a top plan view, and
the magnetic sensor is arranged on at least one of the connection portion between the first body portion and the turn portion, or the connection portion between the second body portion and the turn portion.

2. A current sensor comprising:
a conductor having
a first terminal portion for inputting a current and a second terminal portion for outputting the current which are arranged on one side in a first axial direction, the second terminal portion being separated from the first terminal portion in a second axial direction intersecting the first axial direction,
a turn portion which is arranged on another side in the first axial direction,
a first body portion which connects one end of the turn portion and the first terminal portion, and
a second body portion which is separated from the first body portion in the second axial direction, to connect another end of the turn portion and the second terminal portion;
a magnetic sensor which is arranged on the conductor or near the conductor; and
a package which encapsulates the turn portion, the first body portion, and the second body portion of the conductor, and the magnetic sensor, and which exposes the first terminal portion and the second terminal portion, wherein
at least one of a cross sectional area of a cross section of the first terminal portion, which is taken along an outer plane of the package, or a cross sectional area of a cross section of the second terminal portion, which is taken along the outer plane of the package, is smaller than a cross sectional area of the turn portion,
a connection portion between the first body portion and the turn portion, and a connection portion between the second body portion and the turn portion, have a rectangular shape in a top plan view, and
the magnetic sensor is arranged on at least one of the connection portion between the first body portion and the turn portion, or the connection portion between the second body portion and the turn portion.

3. The current sensor according to claim 1, wherein
the first body portion has a shape in which a cross sectional area is increased from the connection portion with the turn portion toward a connection portion with the first terminal portion, and the second body portion has a shape in which a cross sectional area is increased from the connection portion with the turn portion toward a connection portion with the second terminal portion,
each of the first terminal portion and the second terminal portion includes a plurality of terminals, and
at least one of totals of cross sectional areas of cross sections of the first terminal portion, which is taken along the outer plane of the package, or cross sections of the second terminal portion, which is taken along the outer plane of the package, is smaller than the cross sectional area of the turn portion.

4. The current sensor according to claim 2, wherein
the first body portion has a shape in which a cross sectional area is increased from the connection portion with the turn portion toward a connection portion with the first terminal portion, and the second body portion has a shape in which a cross sectional area is increased from the connection portion with the turn portion toward a connection portion with the second terminal portion,
each of the first terminal portion and the second terminal portion includes a plurality of terminals, and
at least one of totals of cross sectional areas of cross sections of the first terminal portion, which is taken along the outer plane of the package, or cross sections of the second terminal portion, which is taken along the outer plane of the package, is smaller than the cross sectional area of the turn portion.

5. The current sensor according to claim 1, wherein
the turn portion has a shape of extending from one side in the first axial direction to another side, bending in the second axial direction, and returning to the one side, and
the cross sectional area of the turn portion is given by a cross sectional area on a central axis of the conductor parallel to the first axial direction.

6. The current sensor according to claim 1, wherein
at least one of the cross sectional area of the cross section of the first terminal portion, which is taken along the outer plane of the package, or the cross sectional area of the cross section of the second terminal portion, which is taken along the outer plane of the package, is smaller than a minimum value of a cross sectional area of the connection portion between the turn portion and the first body portion, and a minimum value of a cross sectional area of the connection portion between the turn portion and the second body portion.

7. The current sensor according to claim 2, wherein
at least one of the cross sectional area of the cross section of the first terminal portion, which is taken along the outer plane of the package, or the cross sectional area of the cross section of the second terminal portion, which is taken along the outer plane of the package, is smaller than a cross sectional area of the connection portion between the turn portion and the first body portion, and a cross sectional area of the connection portion between the turn portion and the second body portion.

8. The current sensor according to claim 1, further comprising:
a plurality of signal terminals which are separated from the conductor on one side in the first axial direction, and which are encapsulated in the package with edges being exposed, wherein
at least one signal terminal of the plurality of signal terminals is closer to the turn portion than another signal terminal.

9. The current sensor according to claim 8, wherein
the at least one signal terminal is a GND terminal.

10. The current sensor according to claim 9, wherein
the at least one signal terminal is closer to the turn portion, the first body portion, and the second body portion than the another signal terminal.

11. The current sensor according to claim 8, wherein
when the current sensor is mounted on a mounting substrate, the at least one signal terminal is connected to a footprint, on the mounting substrate, which has a greater area than a footprint to which the another signal terminal is connected.

12. The current sensor according to claim 1, wherein
the magnetic sensor is arranged on the conductor via a dielectric layer, and
a contour of the dielectric layer is positioned between a contour of the magnetic sensor and an outer contour of the conductor.

13. The current sensor according to claim 1, wherein
with respect to a long side and a short side of a rectangular shape, when the long side/the short side is set to be an aspect ratio,
the aspect ratio of a cross section of the conductor in the turn portion is 1.4 to 2.7.

14. The current sensor according to claim 13, wherein
the aspect ratios in the cross section of the first terminal portion, which is taken along the outer plane of the package, and in the cross section of the second terminal portion, which is taken along the outer plane of the package, are both 1.4 to 2.7.

15. The current sensor according to claim 13, wherein
the aspect ratios of the cross sections of the conductor in the connection portions between the first body portion and the turn portion, and between the second body portion and the turn portion, are both 1.4 to 2.7.

16. The current sensor according to claim 1, wherein
with respect to a long side and a short side of a rectangular shape, when the long side/the short side is set to be an aspect ratio,
the aspect ratios in a cross section of a connection portion between the first terminal portion and the first body portion, and in a cross section of a connection portion between the second terminal portion and the second body portion are both 1.4 to 2.7.

17. The current sensor according to claim 1, wherein
a thickness of the conductor is approximately constant,
at least one of a width of the cross section of the first terminal portion, which is taken along the outer plane of the package, or a width of the cross section of the second terminal portion, which is taken along the outer plane of the package, is smaller than a width of the turn portion.

18. The current sensor according to claim 17, wherein
at least one of a width of a connection portion between the first terminal portion and the first body portion, or a width of a connection portion between the second terminal portion and the second body portion, is further smaller than a width of the connection portion between the first body portion and the turn portion, and a width of the connection portion between the second body portion and the turn portion.

19. The current sensor according to claim 1, wherein
the current sensor includes any magnetoresistance element of a tunnel magnetoresistance element (TMR), a giant magnetoresistance element (GMR), or an anisotropic magnetoresistance element (AMR).

20. The current sensor according to claim 1, wherein
the magnetic sensor includes a first magnetic sensor and a second magnetic sensor,
the first magnetic sensor is arranged on the connection portion between the first body portion and the turn portion,
the second magnetic sensor is arranged on the connection portion between the second body portion and the turn portion,
each of the first magnetic sensor and the second magnetic sensor includes any magnetoresistance element of a tunnel magnetoresistance element (TMR), a giant magnetoresistance element (GMR), or an anisotropic magnetoresistance element (AMR), and
the first magnetic sensor and the second magnetic sensor have magnetic sensitive directions opposite to each other, and are connected to each other by wiring.
